(19) United States
(12) Patent Application Publication
(10) Pub. No.: US 2016/0111169 A1
(43) Pub. Date: Apr. 21, 2016

(54) MEMORY TEST APPARATUS

(71) Applicant: Samsung Electronics Co., Ltd., Suwon-si (KR)

(72) Inventors: Min-woo Kim, Cheonan-si (KR); Chang-ho Lee, Asan-si (KR); Chang-yong Park, Cheonan-si (KR); Bo-won Han, Asan-si (KR)

(21) Appl. No.: 14/881,579

(22) Filed: Oct. 13, 2015

(30) Foreign Application Priority Data
Oct. 17, 2014 (KR) 10-2014-0141206

(51) Int. Cl. G11C 29/12

(52) U.S. Cl. CPC G11C 29/12005; G11C 29/12015

(57) ABSTRACT

A memory test apparatus includes a test board unit including a first test board configured to load for testing a first memory system including a plurality of memory modules. A second test board is configured to load for testing a second memory system including a plurality of memory modules. A power unit comprises a first power supply unit configured to supply the first test board with a first power for testing the first memory system, a second power supply unit configured to supply the second test board with a second power for testing the second memory system, and a power supply control unit configured to control at least one of a supply timing of the first power and a supply timing of the second power.

### CROSS-REFERENCE TO RELATED APPLICATIONS

This application claims the benefit of Korean Patent Application No. 10-2014-0141206, filed on Oct. 17, 2014, in the Korean Intellectual Property Office, the disclosure of which is incorporated herein in its entirety by reference.

### FIELD OF THE INVENTION

The inventive concept relates to a memory test apparatus, and more particularly, to a memory test apparatus capable of reducing an inrush current and excess of allowable power during a test operation of memory devices.

### BACKGROUND

A test apparatus is used to test the operation of a memory module or a memory system, including memory devices such as hard disk drives (HDDs) or solid state drives (SSDs). Generally, such a test apparatus utilizes power widely used at homes or by industries. As the number of memory devices to be simultaneously tested increases, power specifications will also increase. As the number of memory devices to be tested within a printed circuit board array increases, the number of required power supply units of the test apparatus also increases. Due to the increase in the number of power supply units, the size of a test facility increases and larger current is needed in a distributing board. Thus, radio frequency and environment safety factors must be managed and power lines need to be redesigned to handle the larger current.

### SUMMARY

The inventive concept provides a memory device test apparatus and a memory system test apparatus, which are capable of reducing inrush current and excess of allowable power during an operation of testing a plurality of memory devices or the like.

According to an aspect of the inventive concept, there is provided a memory test apparatus including: a test board unit including a first test board configured to load for testing a first memory system including a plurality of memory modules, and a second test board configured to load for testing a second memory system including a plurality of memory modules; a power unit including a first power supply unit configured to supply the first test board with a first power for testing the first memory system; and a second power supply unit configured to supply the second test board with a second power for testing the second memory system; and a power supply control unit configured to control at least one of a supply timing of the first power and a supply timing of the second power.

Each of the first test board and the second test board may include a plurality of loaders, the first memory system may be loaded on one of the plurality of loaders of the first test board, and the second memory system may be loaded on one of the plurality of loaders of the second test board.

The power supply control unit is configured to control the supply timing of the first power to be different from the supply timing of the second power.

The power supply control unit may control at least one of the supply timing of the first power and the supply timing of the second power to adjust a time interval between the supply timing of the first power and the supply timing of the second power.

The test board unit may further include a first voltage/current detecting unit configured to detect one of a magnitude of a first current flowing through the first test board and a magnitude of a first voltage applied to the first test board in response to the first memory system being loaded on the first test board, and to detect one of a magnitude of a second current flowing through the second test board and a magnitude of a second voltage applied to the second test board in response to the first memory system being loaded on the first test board. The first voltage/current detecting unit may provide the power supply control unit with a first information signal indicating the detected voltage or the detected current. The power supply control unit may control at least one of the supply timing of the first power and the supply timing of the second power in response to the first information signal.

When at least one of the magnitude of the first current, the magnitude of the second current, and a sum of the magnitudes of the first voltage and the second voltage exceeds a reference value, at least one of the supply timing of the first power and the supply timing of the second power may be controlled such that a time interval between the supply timing of the first power and the supply timing of the second power is greater than a previous time interval therebetween.

When at least one of the magnitude of the first current, the magnitude of the second current, and a sum of the magnitudes of the first voltage and the second voltage exceeds a reference value, at least one of the supply timing of the first power and the supply timing of the second power may be controlled such that a time interval between the supply timing of the first power and the supply timing of the second power is greater than a previous time interval therebetween.

The first test board may include a first power converting unit configured to convert the first power into first required power and supply the first required voltage to the first memory system, and the second test board may include a second power converting unit configured to convert the second power into second required power and supply the second required voltage to the second memory system.

The power supply control unit may control a supply timing of the first required power and a supply timing of the second required power.

The first memory system may include a first memory device and a second memory device, and the power supply control unit may control a timing during which the first required power is supplied to the first memory device and a timing during which the first required power is supplied to the second memory device.

The first test board may further include a second voltage/current detecting unit configured to detect at least one of a current flowing through the first memory device and a current flowing through a second memory device, and configured to detect a voltage applied to the first memory device and a voltage applied to the second memory device. The second voltage/current detecting unit may provide the power supply control unit with a second information signal indicating the detected current or the detected voltages. The power supply control unit may control a timing during which the first required power is supplied to the first memory device and a timing during which the first required power is supplied to the second memory device, in response to the second information signal.

According to another aspect of the inventive concept, there is provided a memory system test apparatus including: a test board unit including a plurality of test boards configured to load for testing a plurality of memory systems; a power unit including a plurality of power supply units that respectively correspond to the plurality of test boards and provide the plurality of test boards with powers required for testing; and a power supply control unit configured to set timings during which the plurality of power supply units provide the powers required for testing and adjusts time intervals between the respective timings.

The memory system may include a solid state drive system.

The plurality of power supply units may convert external AC power into DC power. The power unit includes a power switching unit that is electrically connected between a terminal through which the external AC power is supplied and the plurality of power supply units, and the power switching unit may include a plurality of switches. The power supply control unit may control on/off operations of the plurality of switches, wherein timings during which the power supply units supply their corresponding power supply units with the power required for testing are different from one another.

The power supply control unit may include: a timing setting unit that sets timings during which the plurality of power supply units supply the powers required for testing; and a control signal generating unit that generates a control signal, based on a setting result of the supply timings of the powers according to the plurality of power supply units.

According to an aspect of the inventive concept, there is provided a test system comprising a plurality of test boards each including a plurality of memory devices, a plurality of power supplies, each power supply powering a respective test board and a power supply control unit configured to separately gate each power supply with a respective timing to optimize a performance of each test board.

The performance includes limiting an inrush current to the test board by gating a respective power supply by a series of pulses configured to control a rate of current provided to the test board.

The series of pulses are controlled by a current detecting unit interposed between the power supply and the respective test board.

The performance includes limiting an voltage to the test board by gating a respective power supply by a series of pulses configured to control a charging rate to the test board.

The series of pulses are controlled by a voltage detecting unit interposed between the power supply and the respective test board.

### BRIEF DESCRIPTION OF THE DRAWINGS

Exemplary embodiments of the inventive concept will be more clearly understood from the following detailed description taken in conjunction with the accompanying drawings in which:

FIG. 1 is a block diagram of a memory system test apparatus according to an embodiment of the inventive concept.

FIG. 2 is a block diagram of a power unit according to an embodiment of the inventive concept.

FIG. 3 is a block diagram of a power switching unit according to an embodiment of the inventive concept.

FIG. 4 is a block diagram of the power unit according to an embodiment of the inventive concept.

FIG. 5 is a block diagram of a power supply control unit according to an embodiment of the inventive concept.

FIG. 6A and FIG. 6B are time-voltage graphs of a memory system test apparatus according to a related art, and a memory system test apparatus according to an embodiment of the inventive concept respectively.

FIG. 7 is a block diagram of the memory system test apparatus according to an embodiment of the inventive concept.

FIG. 8A, FIG. 8B and FIG. 8C are time-voltage graphs of the memory system test apparatuses according to an embodiment of the inventive concept.

FIG. 9 is a block diagram of a first test board according to an embodiment of the inventive concept.

FIG. 10 is a block diagram of a first test board according to another embodiment of the inventive concept.

FIG. 11 is a block diagram of a first test board according to another embodiment of the inventive concept.

FIG. 12A and FIG. 12B are diagrams of a memory system to be tested while being loaded on a test board.

FIG. 13 is a front view of a memory system test apparatus.

FIG. 14 is a block diagram of a test facility including the memory system test apparatus, according to an embodiment of the inventive concept.

### DETAILED DESCRIPTION

Hereinafter, embodiments of the inventive concept will be described with reference to the accompanying drawings. The inventive concept may, however, be embodied in many different forms and should not be construed as being limited to the embodiments set forth herein; rather, these embodiments are provided so that this disclosure will be thorough and complete, and will fully convey the inventive concept to those of ordinary skill in the art. It should be understood, however, that there is no intent to limit the inventive concept to the particular forms disclosed, but on the contrary, the inventive concept is to cover all modifications, equivalents, and alternatives falling within the spirit and scope of the inventive concept. Like reference numerals denote like elements throughout the specification and drawings. In the drawings, the dimensions of structures are exaggerated or reduced for clarity of the inventive concept.

The terminology used herein is for the purpose of describing particular embodiments only and is not intended to be limiting of the inventive concept. As used herein, the singular forms “a”, “an”, and “the” are intended to include the plural forms as well, unless the context clearly indicates otherwise. It will be understood that terms such as “comprise”, “include”, and “have”, when used herein, specify the presence of stated features, integers, steps, operations, elements, components, or combinations thereof, but do not preclude the presence or addition of one or more other features, integers, steps, operations, elements, components, or combinations thereof.

Though terms like “first” and “second” are used to describe various elements, the elements are not limited to these terms. These terms are used only to differentiate one element from another. Therefore, a first element may be referred to as a second element, and similarly, a second element may be referred to as a firs element, without departing from the scope of the inventive concept.

Unless otherwise defined, all terms used herein, including technical and scientific terms, have the same meaning as commonly understood by one of ordinary skill in the art to which the inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

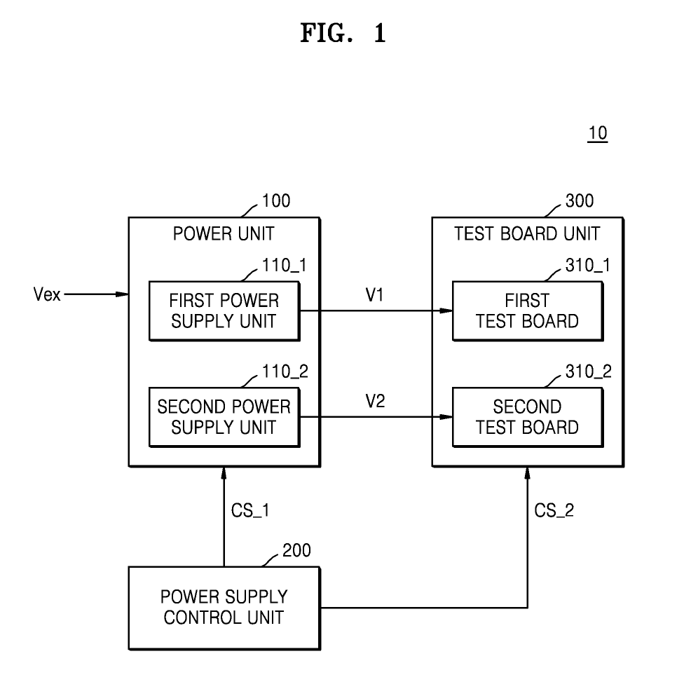

Referring to FIG. 1, the memory system test apparatus 10 may include a power unit 100, a power supply control unit 200, and a test board unit 300. The power unit 100 may be supplied with external power (Vex). The external power Vex may be AC power, while DC power may be needed in a test operation. Accordingly, the power unit 100 may convert the external power Vex, which is AC power, into DC power. The power unit 100 may provide DC power to the test board unit 300 for testing a memory device. A memory device, a memory module, a memory system, or the like, which is to be tested, may be loaded on the test board unit 300. For brevity, references to memory device or memory throughout the specification should be understood to include variations such as memory module and memory system. In addition, the test board unit 300 may receive the power from the power unit 100 and convert the received power into power required for the operation of testing the memory device. The test board unit 300 may perform the test operation by supplying the required power to the memory device to determine whether the memory device is defective.

According to an embodiment, the power unit 100 may include a first power supply unit 110_1 and a second power supply unit 110_2. The test board unit 300 may include a first test board 310_1 and a second test board 320_2. The first power supply unit 110_1 may convert the external power Vex into first power V1 and supply the first power V1 to the first test board 310_1. The second power supply unit 110_2 may convert the external power Vex into second power V2 and supply the second power V2 to the second test board 310_2. The supply of the power may mean either the supply of voltage or current.

The power supply control unit 200 may provide a first control signal CS_1 to the power unit 100, to control a timing during which the power unit 100 supplies the test board unit 300 with power required for testing. According to an embodiment, the power supply control unit 200 may control a timing during which the first power supply unit 110_1 supplies the first power V1 to the first test board 310_1, and a timing during which the second power supply unit 110_2 supplies the second power V2 to the second test board 3102. For example, the first power V1 may be supplied at a first time t1, and the second power V2 may be supplied at a second time t2. The first time t1 may be equal to or different from the second time t2. In addition, when the first time t1 is different from the second time t2, the power supply control unit 200 may increase or decrease a time interval between the first time t1 and the second time t2. Moreover, the first time t1 may be earlier or later than the second time t2.

The voltages, which are supplied to the test board unit 300, are distributed by performing control such that the timing during which the first power supply unit 110_1 supplies the first power V1 is different from the timing at which the second power supply unit 110_2 supplies the second power V2. Accordingly, it is possible to inrush current and the excess of allowable power to the test apparatus by appropriately interleaving V1 and V2.

According to another embodiment, the power supply control unit 200 may provide a second control signal CS_2 to the test board unit 300, to control a timing during which the test board unit 300 supplies required power to the memory device loaded on the test board unit 300. In addition, according to an embodiment, the power supply control unit 200 may provide the first control signal CS_1 and second control signal CS_2 to the power unit 100 and the test board unit 300, respectively, by using a wireless communication method such as RS-485.

The embodiment is not limited to the configuration of FIG. 1. The power unit 100 may include three or more power supply units, and the test board unit 300 may include three or more test boards. In this case, the power supply control unit 200 may control timings during which the power supply units supply power to their corresponding test boards, and may control the respective timings based on the number of power supply units.

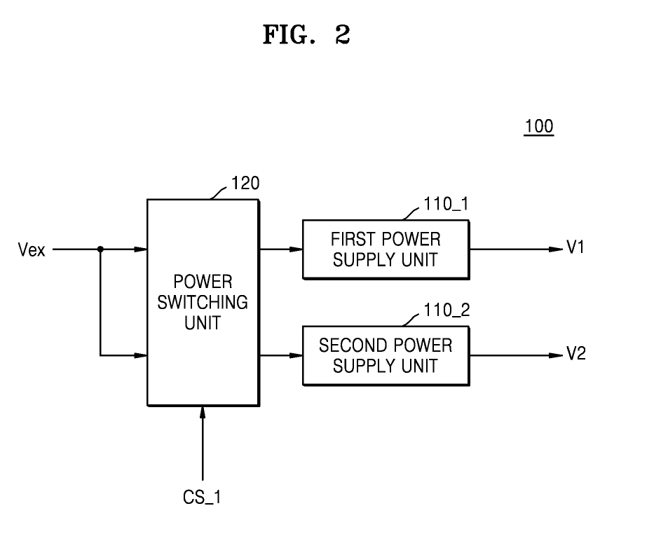

Referring to FIG. 2, the power unit 100 may include a power switching unit 120, a first power supply unit 110_1, and a second power supply unit 110_2. The power switching unit 120 may be electrically connected to an external terminal through which external power Vex is supplied, and may be electrically connected to the first power supply unit 110_1 and the second power supply unit 110_2. Therefore, the power switching unit 120 may electrically connect the external terminal to the first power supply unit 110_1 and the second power supply unit 110_2, or may electrically disconnect the external terminal from the first power supply unit 110_1 and the second power supply unit 110_2. The power supply control unit 200 may provide a first control signal CS_1 to the power switching unit 120, to control the power switching unit 120 such that the external terminal is electrically connected to or disconnected from the first power supply unit 110_1 and the external terminal is electrically connected to or disconnected from the second power supply unit 110_2. In this manner, the power supply control unit 200 may control a timing during which the first power supply unit 110_1 supplies first power V1 and a timing during which the second power supply unit 110_2 supplies second power V2.

The position of the power switching unit 120 is not limited the above-described embodiment. The power switching unit 120 may be positioned between the power supply units 110_1 and 110_2 and the first and second test boards 310_1 and 310_2. Accordingly, the power switching unit 120 may be controlled such that the first power supply unit 110_1 is electrically connected to or disconnected from the first test board 310_1, and the second power supply unit 110_2 is electrically connected to or disconnected from the second test board 310_2. As described above, the power supply control unit 200 may control the power switching unit 120.

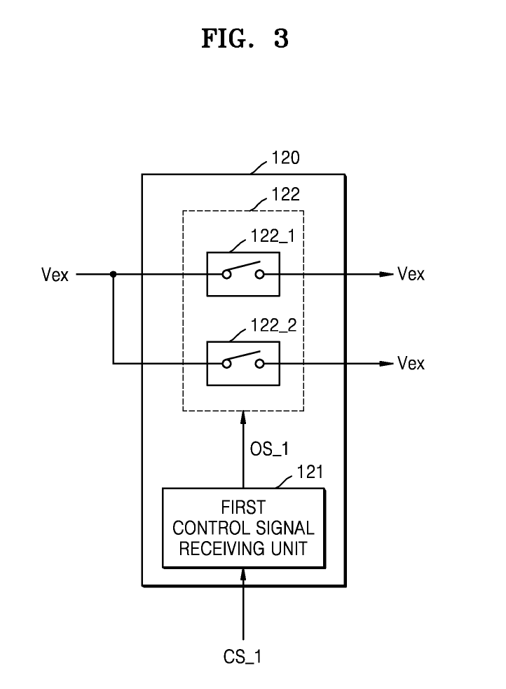

Referring to FIG. 3, the power switching unit 120 may include a first control signal receiving unit 121 and a switch unit 122. The first control signal receiving unit 121 may receive the first control signal CS_1 from the power supply control unit 200. The first control signal CS_1 may include control information on timings during which the respective power supply units supply power, control information on time intervals between the timings, or the like. The first control signal receiving unit 121 may include a buffer (not illustrated) configured to store the first control signal CS_1.

The switch unit 122 may include a first switch 122_1 connected between the external terminal, (through which the external power Vex is supplied), and the first power supply unit 110_1, and a second switch 122_2 connected between the external terminal, (through which the external power Vex is supplied), and the second power supply unit 110_2. When the first switch 122_1 is turned on, the external terminal may be electrically connected to the first power supply unit 110_1, and when the first switch 122_1 is turned off, the external terminal may be electrically disconnected from the first power supply unit 110_1. When the second switch 122_2 is turned on, the external terminal may be electrically connected to the second power supply unit 110_2, and when the second switch 122_2 is turned off, the external terminal may be electrically disconnected from the second power supply unit 110_2.

The first control signal receiving unit 121 may provide a first on/off operation signal OS_1 to the switch unit 122 to control the on/off operations of the first and second switches 122_1 and 122_2, respectively. Referring to FIG. 1 and FIG. 3, for example, the external power Vex may be provided to the first power supply unit 110_1 by turning on the first switch 122_1 at the first time t1, and the first power supply unit 110_1 may convert the external power Vex (being AC power) into the first power V1 (being DC power) and provide the first power V1 to the first test board 310_1. Similarly, the external power Vex may be provided to the second power supply unit 110_2 by turning on the second switch 122_2 at the second time t2, and the second power supply unit 110_2 may convert the external power Vex (being AC power) into the second power V2 (being DC power) and provide the second power V2 to the second test board 310_2.

The first time t1 may be equal to or different from the second time t2. In addition, when the first time t1 is different from the second time t2, the power supply control unit 200 may perform control to increase or decrease a time interval between the first time t1 and the second time t2. Moreover, the first time t1 may be earlier or later than the second time t2.

In this manner, the voltages, which are supplied to the test board unit 300, are temporally distributed by performing control such that the timing at which the first power supply unit 110_1 supplies the first power V1 is different from the timing at which the second power supply unit 110_2 supplies the second power V2. Accordingly, it is possible to reduce inrush current and excess of allowable power to the test apparatus.

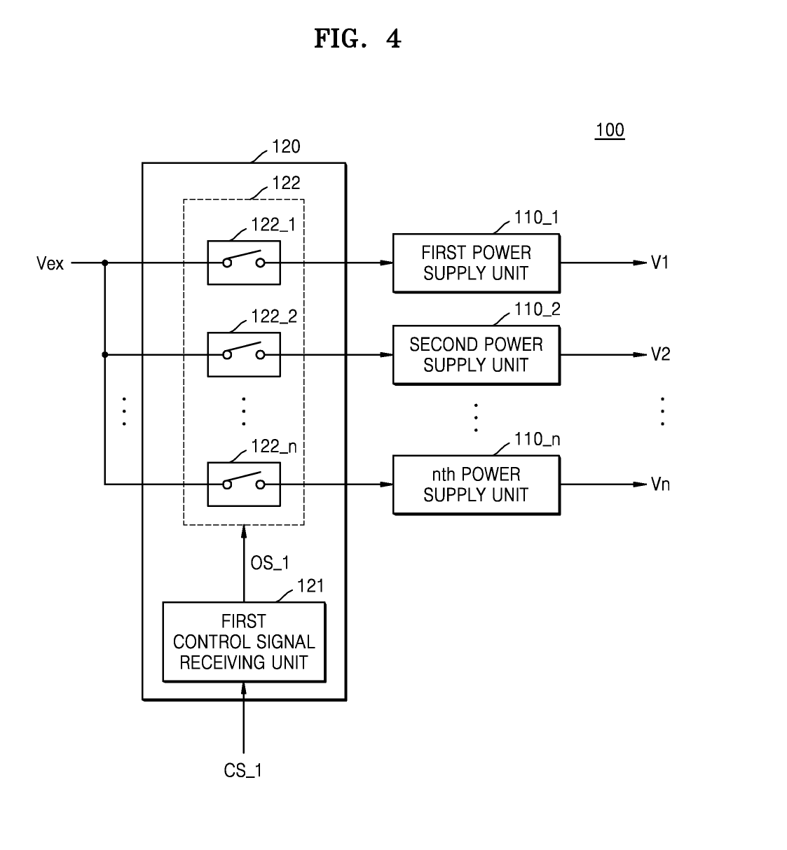

Referring to FIG. 4, the power unit 100 may include n power supply units 110_1 to 110_n (where n is a natural number) and a power switching unit 120. The power switching unit 120 may include a first control signal receiving unit 121 and a switch unit 122, and the switch unit 122 may include n switches 122_1 to 122_n. The switches 122_1 to 122_n may respectively correspond to the power supply units 110_1 to 110_n. For example, the first switch 122_1 may correspond to the first power supply unit 110_1, and the n^{th} switch 122_n may correspond to the n^{th} power supply unit 110_n.

The first control signal receiving unit 121 may receive the first control signal CS_1, generate a first on/off operation signal OS_1 based on the first control signal CS_1, and provide the first on/off operation signal OS_1 to the switch unit 122 to control the on/off operations of the switches 122_1 and 122_2. In this manner, the power supply control unit 200 may control a timing during which the first power supply unit 110_1 supplies first power V1, a timing during which the second power supply unit 110_2 supplies second power V2, and a timing during which the n^{th} power supply unit 110_n supplies n^{th} power Vn. The power supply control unit 200 may control the timings differently. Furthermore, the power supply control unit 200 may control the timings during which specific power supply units supply specific powers to become equal to each other. For example, the timing during which the first power supply unit 110_1 supplies the first power V1 becomes equal to the timing during which the second power supply unit 110_2 supplies the second power V2, and the timing during which the third power supply unit 110_3 supplies the third power V3 becomes equal to the timing during which the fourth power supply unit 110_4 supplies the fourth power V4. However, the inventive concept is not limited to the above-described embodiment, and the timings during which the power supply units supply powers may be variously controlled.

As described above, the test apparatus, including a plurality of power supply units, variously controls the timings during which the power supply units supply the powers to enable testing of more memory devices. Thus, the powers, which are supplied to a test board unit, may be distributed to removing negative factors such as inrush current.

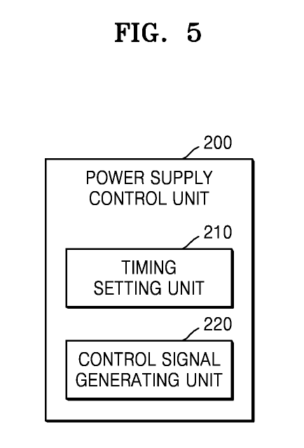

Referring to FIG. 5, the power supply control unit 200 may include a timing setting unit 210 and a control signal generating unit 220. The timing setting unit 210 may set the timing during which the first power supply unit 110_1 supplies the first power V1, the timing during which the second power supply unit 110_2 supplies the second power V2, and the timing during which the n^{th} power supply unit 110_n supplies the n^{th} power Vn. For example, the timing of supplying the first power V1, the timing of supplying the second power V2, and the timing of supplying the n^{th} power Vn may be set as the first time t1, the second time t2, and the n^{th} time tn, respectively. To sequentially supply the powers, the timings of supplying the powers may be set sequentially (e.g. the first time t1 is less than the second time t2, and the n-1^{th} time is less than the n^{th} time n), such that the first to n^{th} power supply units 110_1 to 110_n sequentially supply the first to n^{th} powers V1 to Vn. In addition, the respective timings may be set to adjust the time interval between the respective timings. The timings may be set based on the number of power supply units of the power unit 100 of FIG. 4. According to an embodiment, when the number of power supply units that supply constant power to a test board unit is increased, as compared to the related art, the power supplied to the test board unit may be greater than the related art. Accordingly, the timings may be set such that the time interval between the timings during which the plurality of power supply units supply the powers is greater than the related art. As a result, the plurality of power supply units may sequentially supply the powers for longer time intervals.

The control signal generating unit 220 may generate the first control signal CS_1 based on information on the timing set by the timing setting unit 210 such that the power supply units supply the powers, information on the time interval between the timings at which the power supply units supply the powers, or the like. The control signal generating unit 220 may receive the information on the timing set from the timing setting unit 210 such that the power supply units supply the powers, information on the time interval between the timings at which the power supply units supply the powers, or the like. As described above with reference to FIG. 1, the power supply control unit 200 may control the timing during which the test board unit 300 supplies power required for testing to the memory device loaded on the test board unit 300, and the timing setting unit 210 may set the timing during which the required power is supplied to the memory device attached to the test board unit 300 and may set the respective timings so as to adjust the time interval between the timings.

The control signal generating unit 220 may generate the second control signal CS_2 based on information on the timing set by the timing setting unit 210 such that the required power is supplied to the memory device loaded on the test board unit 300, information on the time interval between the respective timings, or the like. The inventive concept is not limited to this embodiment, and the timing setting unit 210 and the control signal generating unit 220 may be constituted as one block.

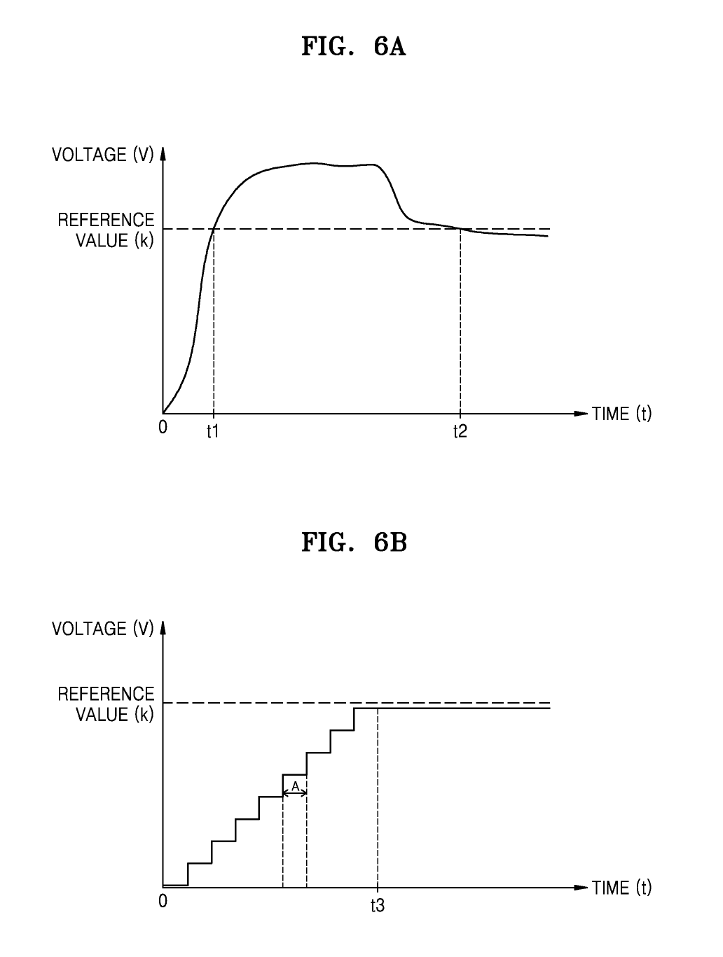

The memory system test apparatus according to a related art may include a plurality of power supply units to test a plurality of memory systems. Referring to FIG. 6A, the memory system test apparatus according to the related art may exceed a reference value k of the allowable voltage until the time t2 due to factors such as inrush current generated by synchronizing the timing at which the plurality of power supply units supply the powers during the time t1. Consequently, due to the voltage exceeding the reference value k, the test operation of the memory system test apparatus may be obstructed.

Referring to FIG. 1 and FIG. 6B, the memory system test apparatus according to an embodiment separately controls the timings during which the plurality of power supply units supply the powers, such that the plurality of power supply units sequentially supply the powers until the time t3. In this manner, because the memory system test apparatus does not exceed the reference value k of the allowable voltage, more memory systems may be efficiently tested. In addition, in a case where a plurality of power supply units are further included to test more memory systems at a time, the timings during which the power supply units supply the powers may be controlled to increase the time interval A between the timings during which the power supply units supply the powers.

Therefore, even when a very large number of power supply units are included, the memory system test apparatus according to an embodiment may not exceed the reference value k of the allowable voltage.

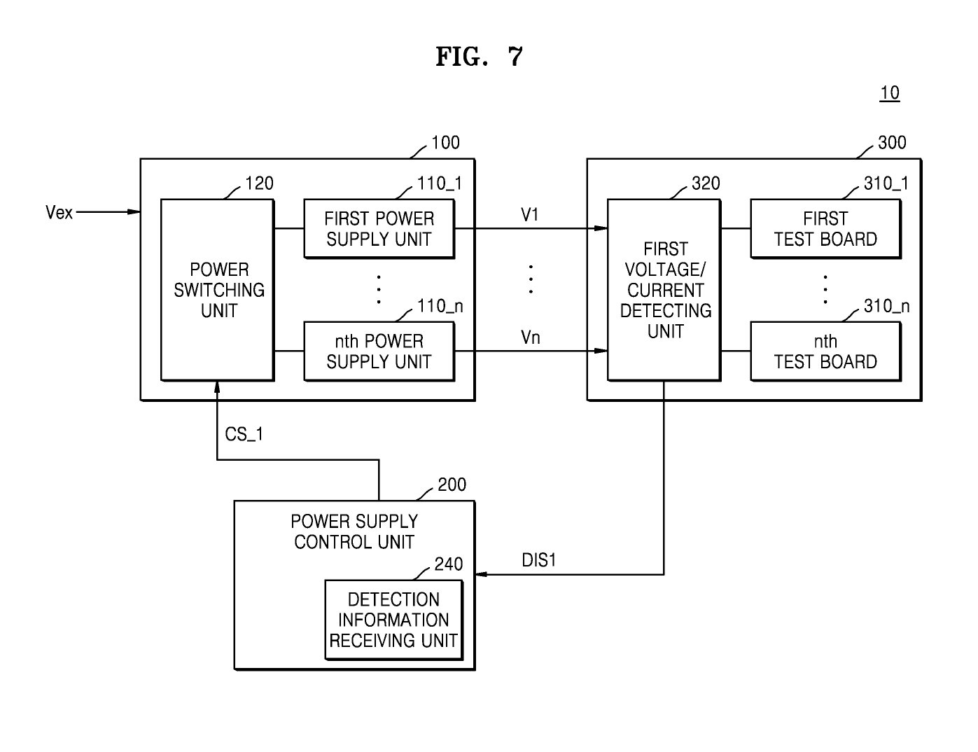

Referring to FIG. 7, the memory system test apparatus 10 may include a power unit 100, a power supply control unit 200, and a test board unit 300. The power unit 100 may include a plurality of power supply units 110_1 to 110_n and a power switching unit 120. In one embodiment, the power supply control unit 200 and the power switching unit 120 are substantially the same as those described with reference to FIG. 3. The test board unit 300 may include a plurality of test boards 310_1 to 310_n and a first voltage/current detecting unit 320. The plurality of test boards 310_1 to 310_n include loaders that load memory systems. The first voltage/current detecting unit 320 may detect the magnitude of current flowing through the test boards when the power supply units 110_1 to 110_n supply the powers to the test boards. According to an embodiment, the first voltage/current detecting unit 320 may detect the magnitude of current flowing through the first test board 310_1 when the first power supply unit 110_1 supplies the first power V1 to the first test board 310_1. In addition, the first voltage/current detecting unit 320 may detect the magnitude of current flowing through the n^{th} test board 310_n when the n^{th} power supply unit 110_n supplies the nth power V1 to the n^{th} test board 310_n. In this manner, it is possible to detect whether or not inrush current obstructing the test apparatus occurs.

According to another embodiment, the first voltage/current detecting unit 320 may detect the magnitude of voltages applied to the test boards 310_1 to 310_n when the power supply units 110_1 to 110_n supply the first to n^{th} powers V1 to Vn to the test boards 310_1 to 310_n. For example, the first voltage/current detecting unit 320 may detect the magnitude of the voltage applied to the first test board 310_1 when the first power supply unit 110_1 supplies the first power V1 to the first test board 310_1. In addition, the first voltage/current detecting unit 320 may detect the magnitude of the voltage applied to the n^{th} test board 310_n when the n^{th} power supply unit 110_n supplies the n^{th} power V1 to the n^{th} test board 310_n. Furthermore, the first voltage/current detecting unit 320 may sum the detected magnitudes of the voltages and detect whether or not the test apparatus exceeds an allowable voltage reference value.

The first voltage/current detecting unit 320 may generate a first information signal DIS1 with respect to the detected current flowing through the test boards 310_1 to 310_n or the detected voltages applied to the test boards 310_1 to 310_n, and provide the first information signal DIS1 to the power supply control unit 200. The first information signal DIS1 may include at least one selected from the detected magnitudes of current flowing through the test boards 310_1 to 310_n, the detected magnitudes of voltages applied to the test boards 310_1 to 310_n, and the sum of the detected magnitudes of voltages.

The power supply control unit 200 of FIG. 7 may further include a detection information receiving unit 240, in addition to the other components of the power supply control unit 200 of FIG. 5. The detection information receiving unit 240 may include a buffer (not illustrated) configured to receive and store the first information signal DIS1. Based on the first information signal DIS1, the power supply control unit 200 may control timings during which the power supply units 110_1 to 110_n supply the powers to their corresponding test boards 310_1 to 310_n. According to an embodiment, in a case where the detected magnitude of current exceeds the allowable current reference value, the power supply control unit 200 may control the timings during which the power supply units 110_1 to 110_n supply the powers to their corresponding test boards 310_1 to 310_n to reduce the detected magnitude of current. For example, the power supply control unit 200 may perform control such that the time intervals between the timings during which the power supply units 110_1 to 110_n supply the powers to their corresponding test boards 310_1 to 310_n are increased. According to another embodiment, in a case where the sum of the detected magnitudes of voltages exceeds the allowable voltage reference value, the power supply control unit 200 may control the timings at which the power supply units 110_1 to 110_n supply the powers to their corresponding test boards 310_1 to 310_n so as to reduce the detected magnitudes of voltages. This method may be substantially the same as the method of reducing the magnitude of current, as described above.

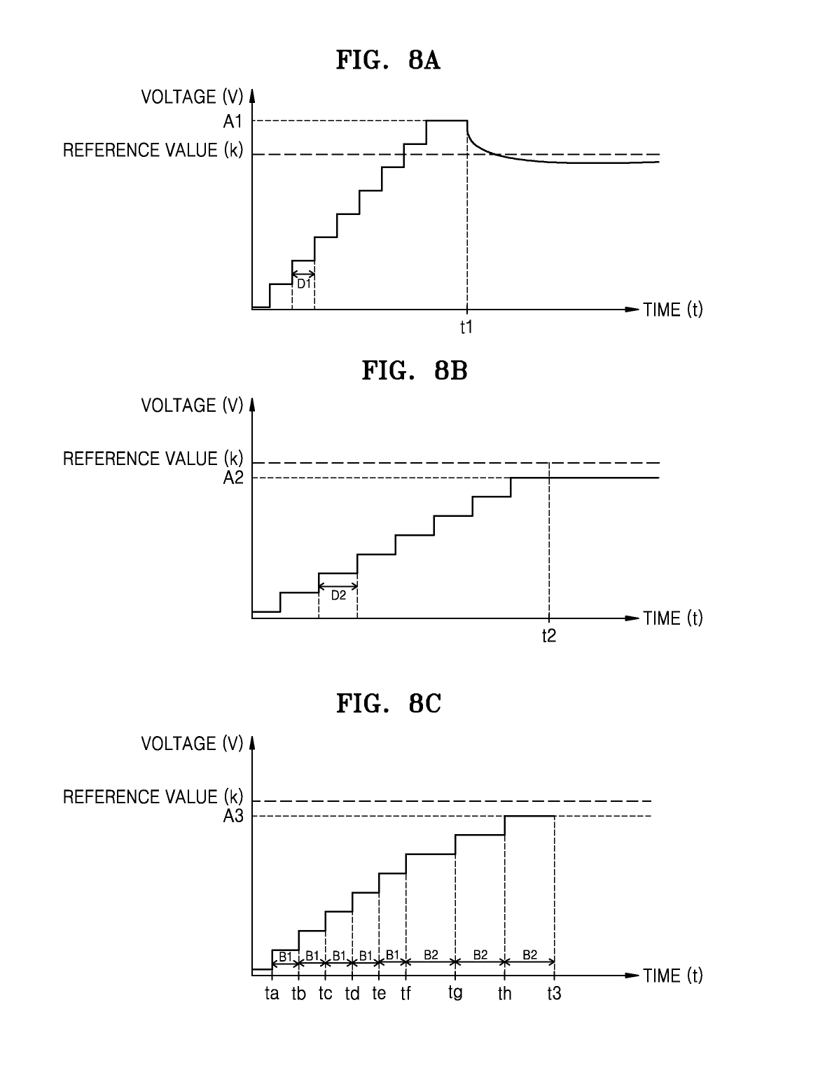

The memory system test apparatus may include a plurality of power supply units to test a plurality of memory systems. FIG. 8A is a graph showing the timing control when the plurality of power supply units supply powers at time intervals D1. Although the power supply units sequentially supply the powers, the sum of the voltages applied to the test boards may exceed the allowable voltage reference value k of the test apparatus because the time interval between the timings is relatively narrow. The excess of the allowable voltage reference value k may have negative influence on the test apparatus.

FIG. 8B is a graph showing the timing control when the plurality of power supply units supply powers at time intervals D2 to prevent the excessive voltage shown in FIG. 8A. Because the time interval D2 is greater than the time interval D1, the timing control may be performed such that the time interval between the power supply timings is greater than that in FIG. 8A. By suppressing the occurrence of inrush current through the above-described control, the sum of the voltages applied to the test boards may not exceed the allowable voltage reference value k of the test apparatus. Thus, more memory systems may be tested at the same time.

With reference to FIG. 8C, in another embodiment the timing control may be performed such that the time intervals between the timings at which the power supply units supply the powers is varied. The timing control may be performed such that some of the power supply units have the time interval B1 between the power supply timings thereof, and the other power supply units have the time interval B2 between the power supply timings thereof. However, the inventive concept is not limited to the above-described embodiment, and the timing control may be performed such that the power supply units have different time intervals between the power supply timings thereof.

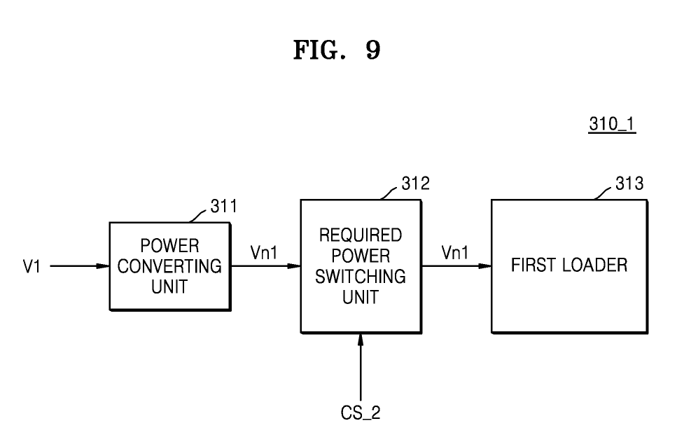

Referring to FIG. 9, the first test board 310_1 may include a power converting unit 311, a required power switching unit 312, and a first loader 313. The first loader 313 may load a first memory system (not illustrated) to be tested. The first memory system may include a plurality of memory devices that are mounted on a printed circuit board (PCB). The first power supply unit may supply the first power V1 to the power converting unit 311. The power converting unit 311 may convert the first power V1 into a first required power Vn1 to test the first memory system loaded on the first test board 310_1. According to an embodiment, the first required power Vn1 may be in a predetermined range and may be less than the first power V1. As described above, because the power may be supplied in the form of current or voltage, the first required power Vn1 may be current or voltage respectively.

The required power switching unit 312 may be electrically connected to the power converting unit 311 and may be electrically connected to the first loader 313. Accordingly, the required power switching unit 312 may electrically connect the power converting unit 311 to the first loader 313 or electrically disconnect the power converting unit 311 from the first loader 313. The power supply control unit 200 may control the required power switching unit 312 by providing the second control signal CS_2 to the required power switching unit 312, such that the power converting unit 311 and the first loader 313 are electrically connected to or electrically disconnected from each other. In this manner, the power supply control unit 200 may control the timings during which the power converting unit 311 supplies the first required power Vn1 to the plurality of memory devices included in the first memory system.

The first test board 310_1 may include a central processing unit (CPU) (not illustrated), and the CPU may control downloading of a software program for performing the test. The software program may control a controller of a memory device, for example, a controller of a solid state drive (SSD). Accordingly, the controller of the SSD may perform the test for itself According to an embodiment, the SSD may have a built-in self-test (BIST) function.

The timings during which the power converting unit 311 supplies the first required power Vn1 to the memory devices may be equal to or different from one another. Furthermore, the timing of supplying the required power may vary, and the required power may be sequentially supplied to the memory devices. In this manner, it is possible to reduce factors such as inrush current applied to the memory devices included in the memory system during the testing of the memory system.

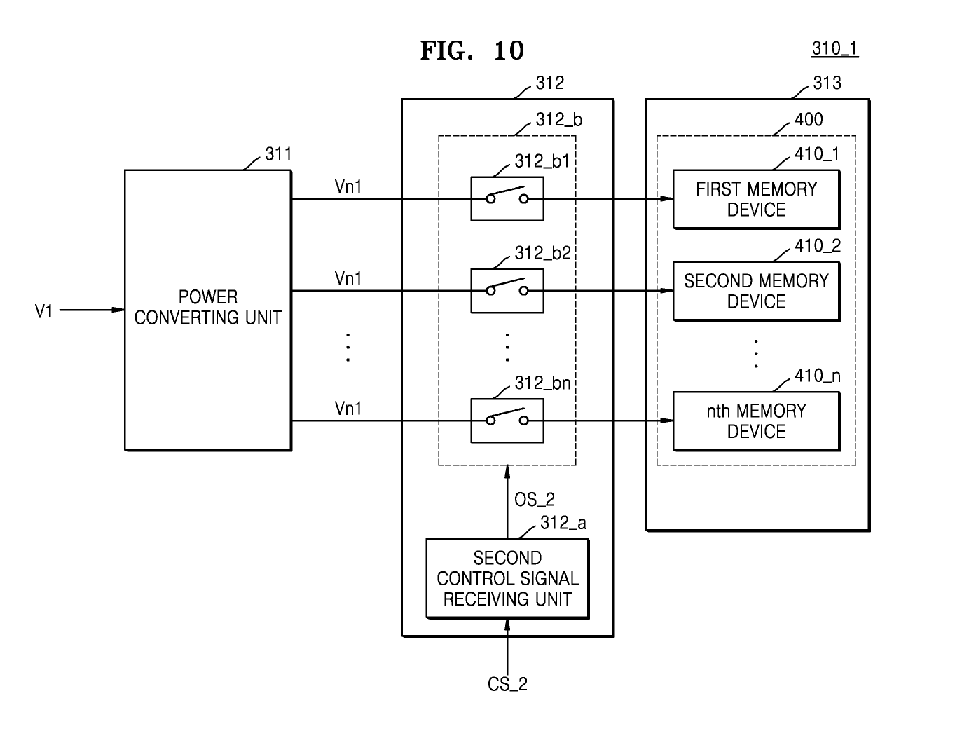

Referring to FIG. 10, the first test board 310_1 may include a power converting unit 311, a required power switching unit 312, and a first loader 313. A first memory system 400 may be loaded on the first loader 313, and the first loader 313 may include a plurality of transfer units (not illustrated) configured to transfer the first required power Vn1. By providing the first required power Vn1 to the plurality of transfer units (not illustrated), the plurality of transfer units (not illustrated) may transfer the first required power Vn1 to the memory system.

The memory system 400 may include a first memory device 410_1, a second memory device 410_2, and an n^{th} memory device 410_n. In addition, the required power switching unit 312 may include a second control signal receiving unit 312_a and a switch unit 312_b, and the switch unit 312_b may include n switches 312_b1 to 312_bn. The switches 312_b1 to 312_bn may be electrically connected to the memory devices 410_1 to 410_n, respectively. The first switch 312_b1 may correspond to the first memory device 410_1, and the n^{th} switch 312_bn may correspond to the n^{th} memory device 410_n. According to an embodiment, the memory devices 410_1 to 410_n may be electrically connected to the transfer units (not illustrated) and may be electrically connected to the switches 312_b1 to 312_bn through the transfer units (not illustrated).

The second control signal receiving unit 312_a may receive the second control signal CS_2, generate the second on/off operation signal OS_2 based on the second control signal CS_2, and control the on/off operations of the switches 312_b1 to 312_bn by providing the second on/off operation signal OS_2 to the switch unit 312_b. In this manner, the power supply control unit 200 may control the timing during which the power converting unit 311 supplies the first required power Vn1 to the first memory device 410_1, the timing during which the power converting unit 311 supplies the first required power Vn1 to the second memory device 410_2, and the timing during which the power converting unit 311 supplies the first required power Vn1 to the n^{th} memory device 410_n. The timings may be separately controlled, and the first required power Vn1 may be supplied to the memory devices 410_1 to 410_n.

Furthermore, in a case where the transfer units (not illustrated) are included, the timing during which the power converting unit 311 supplies the first required power Vn1 to the n^{th} memory device 410_n may be the same timing during which the power converting unit 311 supplies the first required power Vn1 to the transfer unit (not illustrated) that is electrically connected to the n^{th} memory device 410_n.

The timings during which the first required power Vn1 is supplied may be varied. In addition, such a configuration may be applied to other test boards included in the test board unit.

In this manner, it is possible to remove negative factors such as inrush current that may flow through the memory device.

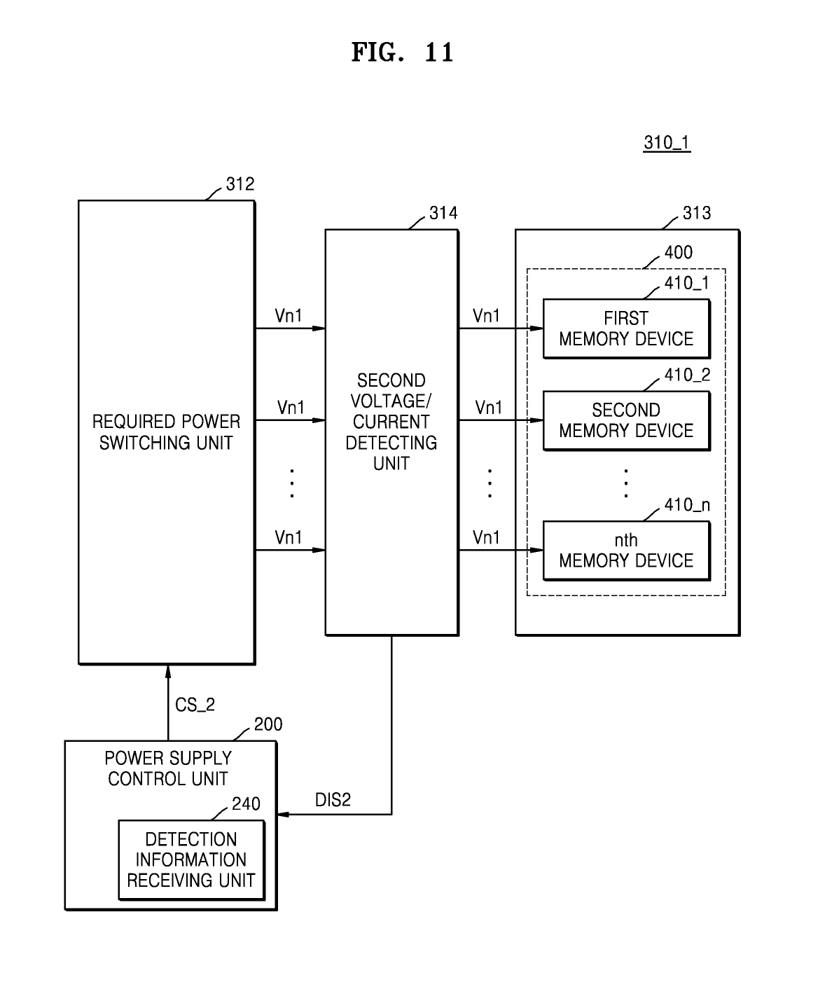

Referring to FIG. 11, the first test board 310_1 may further include a second voltage/current detecting unit 314, in addition to the components of the first test board 310_1 of FIG. 10. The second voltage/current detecting unit 314 may detect the magnitude of current flowing through the memory devices 410_1 to 410_n when the power converting unit supplies the first required power Vn1 to the memory devices 410_1 to 410_n. According to an embodiment, the second voltage/current detecting unit 314 may detect the magnitude of current flowing through the first memory device 410_1. In addition, the second voltage/current detecting unit 314 may detect the magnitude of current flowing through the n^{th} memory device 410_n. In this manner, it is possible to detect whether or not inrush current obstructing the test apparatus occurs.

According to another embodiment, the second voltage/current detecting unit 314 may detect the magnitude of voltages applied to the memory devices 410_1 to 410_n when the power converting unit supplies the first required power Vn1 to the memory devices 410_1 to 410_n. For example, the second voltage/current detecting unit 314 may detect the magnitude of the voltage applied to the first memory device 410_1. In addition, the second voltage/current detecting unit 314 may detect the magnitude of the voltage applied to the n^{th} memory device 410_n.

The second voltage/current detecting unit 314 may generate a second information signal DIS2 with respect to the detected current flowing through the memory devices 410_1 to 410_n or the detected voltages applied to the memory devices 410_1 to 410_n and provide the second information signal DIS2 to the power supply control unit 200. The second information signal DIS2 may include at least one selected from the detected magnitudes of current flowing through the memory devices 410_1 to 410_n and the detected voltages applied to the memory devices 410_1 to 410_n.

The power supply control unit 200 may further include a detection information receiving unit 240, in addition to the components of the power supply control unit 200 of FIG. 5. The detection information receiving unit 240 may include a buffer (not illustrated) configured to receive and store the second information signal DIS2. Based on the first information signal DIS1, the power supply control unit 200 may control the timings during which the power supply unit supplies the first required power to the memory devices 410_1 to 410_n, or the timings during which the power converting unit supplies the first required power Vn1 to the transfer units (not illustrated) that are electrically connected to the memory devices 410_1 to 410_n.

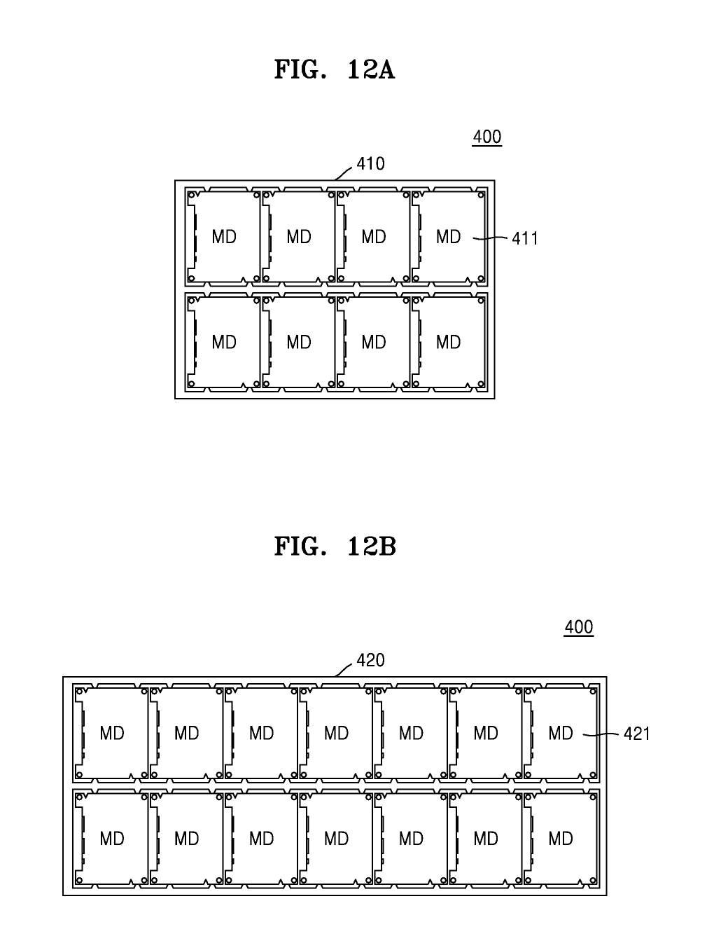

Referring to FIG. 12A, the memory system 400 may include a plurality of memory devices 411. According to an embodiment, the memory device 411 may be an SSD and have a BIST function. The memory system 400 may include a first PCB 410, on which the plurality of memory devices 411 are mounted. The first PCB 410 may include printed circuits (not illustrated) capable of supplying the required powers for testing the memory devices, and the first PCB 410 may include a loader (not illustrated) configured to be loaded on the loader of the test board.

Referring to FIG. 12B, the memory system 400 may include more memory devices 421 than the memory system 400 of FIG. 12A. Accordingly, a second PCB 420 may be larger than the first PCB 410 and may include a larger loader. Hence, the loader of the test board that loads the second PCB 420 may be larger than the loader that loads the first PCB 410.

To test more memory devices at the same time, the size of the loader of the test board in the memory system test apparatus may be adjusted according to the embodiment.

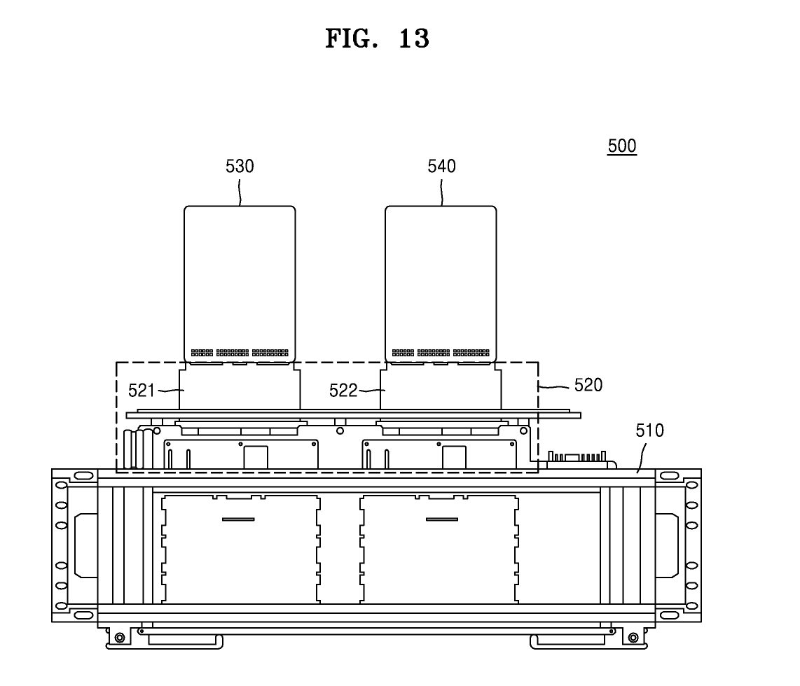

Referring to FIG. 13, the memory system test apparatus 500 may include a memory system test apparatus body 510 and a test board unit 520. A power unit, a CPU, or the like may be included in the memory system test apparatus body 510. A first memory system 530 and a second memory system 540 may be loaded on the test board unit 520. Each of the first memory system 530 and the second memory system 540 may include a plurality of memory devices and a PCB. According to an embodiment, the first memory system 530 and the second memory system 540 may include different numbers of memory devices. Accordingly, the size of a first loader 521 may be different than that of a second loader 522 included in the test board unit 520, and different numbers of transfer units (not illustrated) may be included in the first loader 521 and the second loader 522.

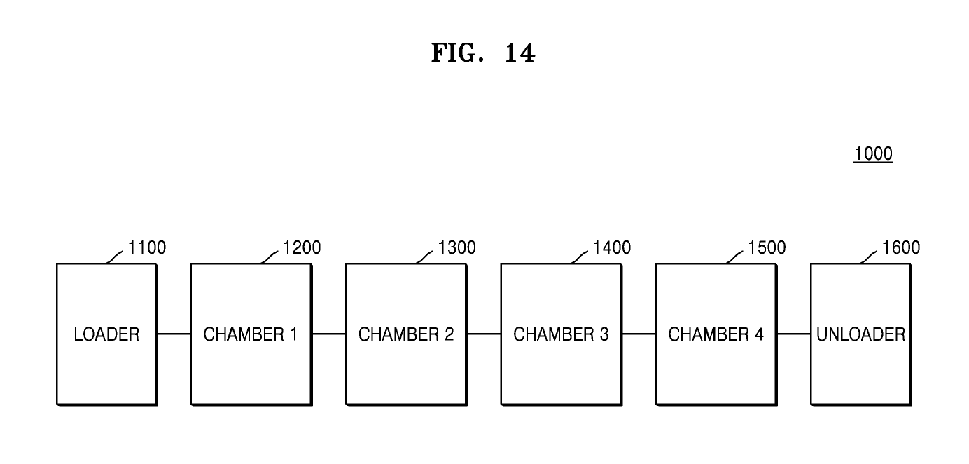

Referring to FIG. 14, the test facility 1000 may include a loader 1100, first to fourth chambers 1200 to 1500 respectively, and an unloader 1600. The loader 1100 may automatically load a plurality of memory systems to be tested into the first to fourth chambers 1200 to 1500, and the unloader 1600 may unload the loaded memory systems. At least one selected from the first to fourth chambers 1200 to 1500 may correspond to the memory system test apparatus 10 described above with reference to FIG. 1, and may test more memory systems at the same time by controlling the timings at which the powers required for testing are supplied.

While the inventive concept has been particularly shown and described with reference to embodiments thereof, it will be understood that various changes in form and details may be made therein without departing from the spirit and scope of the following claims.

What is claimed is:

1. A memory test apparatus comprising:
a test board unit comprising:
a first test board configured to load for testing a first memory system including a plurality of memory modules; and
a second test board configured to load for testing a second memory system including a plurality of memory modules;
a power unit comprising:
a first power supply unit configured to supply the first test board with a first power for testing the first memory system;
a second power supply unit configured to supply the second test board with a second power for testing the second memory system; and
a power supply control unit configured to control at least one of a supply timing of the first power and a supply timing of the second power.

2. The memory test apparatus of claim 1, wherein
each of the first test board and the second test board comprises a plurality of loaders,
the first memory system is loaded on one of the plurality of loaders of the first test board, and
the second memory system is loaded on one of the plurality of loaders of the second test board.

3. The memory test apparatus of claim 1, wherein the power supply control unit is configured to control the supply timing of the first power to be different from the supply timing of the second power.

4. The memory test apparatus of claim 3, wherein the power supply control unit controls at least one of the supply timing of the first power and the supply timing of the second power to adjust a time interval between the supply timing of the first power and the supply timing of the second power.

5. The memory test apparatus of claim 1, wherein
the test board unit further comprising a first voltage/current detecting unit configured to detect one of a magnitude of a first current flowing through the first test board and a magnitude of a first voltage applied to the first test board in response to the first memory system being loaded on the first test board, and to detect one of a magnitude of a second current flowing through the second test board and a magnitude of a second voltage applied to the second test board in response to the first memory system being loaded on the first test board,
the first voltage/current detecting unit providing the power supply control unit a first information signal indicating the detected voltage or the detected current, and
the power supply control unit controlling at least one of the supply timing of the first power and the supply timing of the second power in response to the first information signal.

6. The memory test apparatus of claim 5, wherein, when at least one of the magnitude of the first current, the magnitude of the second current, and a sum of the magnitudes of the first voltage and the second voltage exceeds a reference value, at least one of the supply timing of the first power and the supply timing of the second power is controlled such that a time interval between the supply timing of the first power and the supply timing of the second power is greater than a previous time interval therebetween.

7. The memory test apparatus of claim 5, wherein, when at least one of the magnitude of the first current, the magnitude of the second current, and a sum of the magnitudes of the first voltage and the second voltage exceeds a reference value, at least one of the supply timing of the first power and the supply timing of the second power is controlled such that a time interval between the supply timing of the first power and the supply timing of the second power is less than a previous time interval therebetween.

8. The memory test apparatus of claim 1, wherein
the first test board comprises a first power converting unit configured to convert the first power into first required power and supply the first required voltage to the first memory system, and
the second test board comprises a second power converting unit configured to convert the second power into second required power and supply the second required voltage to the second memory system.

9. The memory test apparatus of claim 8, wherein the power supply control unit controls a supply timing of the first required power and a supply timing of the second required power.

10. The memory test apparatus of claim 8, wherein
the first memory system comprises a first memory device and a second memory device, and
the power supply control unit controls a timing during which the first required power is supplied to the first memory device and a timing during which the first required power is supplied to the second memory device.

11. The memory test apparatus of claim 10, wherein
the first test board further comprises a second voltage/current detecting unit configured to detect at least one of a current flowing through the first memory device and a current flowing through the second memory device, and configured to detect a voltage applied to the first memory device and a voltage applied to the second memory device,
the second voltage/current detecting unit providing the power supply control unit with a second information signal indicating the detected current or the detected voltages, and
the power supply control unit controlling a timing during which the first required power is supplied to the first memory device and a timing during which the first required power is supplied to the second memory device, in response to the second information signal.

12. A memory test apparatus comprising:
a test board unit comprising a plurality of test boards configured to load for testing a plurality of memory systems;
a power unit comprising a plurality of power supply units respectively corresponding to the plurality of test boards and providing the plurality of test boards with powers required for testing; and
a power supply control unit configured to set timings during which the plurality of power supply units provide the powers required for testing and adjusts time intervals between the respective timings.

13. The memory test apparatus of claim 12, wherein the memory system comprises a solid state drive system.

14. The memory test apparatus of claim 12, wherein
the plurality of power supply units convert external AC power into DC power,
the power unit includes a power switching unit electrically connected between a terminal through which the external AC power is supplied and the plurality of power supply units, the power switching unit including a plurality of switches, and
the power supply control unit controls on/off operations of the plurality of switches, wherein timings during which the power supply units supply their corresponding power supply units with the power required for testing are different from one another.

15. The memory test apparatus of claim 12, wherein
the power supply control unit comprises:
a timing setting unit that sets timings during which the plurality of power supply units supply the powers required for testing; and
a control signal generating unit that generates a control signal, based on a setting result of the supply timings of the powers according to the plurality of power supply units.

16. A test system comprising:
a plurality of test boards each including a plurality of memory devices;
a plurality of power supplies, each power supply powering a respective test board; and
a power supply control unit configured to separately gate each power supply with a respective timing to optimize a performance of each test board.

17. The system of claim 16 wherein optimizing the performance includes limiting an inrush current to the test board by gating a respective power supply by a series of pulses configured to control a rate of current provided to the test board.

18. The system of claim 17 wherein the series of pulses are controlled by a current detecting unit interposed between the power supply and the respective test board.

19. The system of claim 16 wherein optimizing the performance includes limiting a voltage to the test board by gating a respective power supply by a series of pulses configured to control a charging rate to the test board.

20. The system of claim 19 wherein the series of pulses are controlled by a voltage detecting unit interposed between the power supply and the respective test board.
